(19) United States
(12) Patent Application Publication
(10) Pub. No.: US 2020/0340093 A1
(43) Pub. Date: Oct. 29, 2020

(54) MASK

(71) Applicant: Truly (Huizhou) Smart Display Limited, Guangdong (CN)

(72) Inventors: Junhai SU, Guangdong (CN); Jiaoguo GONG, Guangdong (CN); Junxiong WU, Guangdong (CN); Yinggang RAN, Guangdong (CN); Xianjun KE, Guangdong (CN); Jianhua LI, Guangdong (CN)

(21) Appl. No.: 16/758,418

(22) PCT Filed: Oct. 24, 2018
(86) PCT No.: PCT/CN2018/111670

§ 371 Date: Apr. 23, 2020

(30) Foreign Application Priority Data
Oct. 25, 2017 (CN) 201711006705.4

(51) Int. Cl. C23C 14/04; C23C 14/24; H01L 51/00

(52) U.S. Cl. CPC C23C 14/042; H01L 27/3244; H01L 51/0011; C23C 14/24

(57) ABSTRACT

A mask, including a dummy region and at least one effective evaporation region. The at least one effective evaporation region is provided with several first through holes. The dummy region is provided with several second through holes. The second through hole has a same shape as the first through hole, a dimension of the second through hole is equal to a dimension the first through hole, and spacing between the second through holes is equal to spacing between the first through holes. The second through holes are disposed in the dummy region on the outer side of the effective evaporation region. The second through hole has the same shape, dimension, and spacing as the first through hole.

### CROSS REFERENCE TO RELATED APPLICATION

This application claims priority to Chinese Patent Application No. 201711006705A, filed with the China National Intellectual Property Administration on Oct. 25, 2017, and entitled “MASK”, which is incorporated herein by reference in its entirety.

### BACKGROUND OF THE INV ENTION

This application relates to the field of organic light-emitting display manufacturing technologies, and in particular, to a mask.

In AMOLED (Active-matrix organic light emitting diode, active matrix organic light-emitting diode) manufacturing processes, an evaporation process most affects a yield rate. A basic procedure of the evaporation process is to heat and evaporate an organic material, and deposit the organic material on a glass substrate through through holes formed by etching a high-precision fine mask, to form a light-emitting unit.

The high-precision fine mask is usually manufactured through etching. The high-precision fine mask has a thickness less than or equal to 40 urn. Because of the relatively small thickness of the high-precision fine mask, the conventional high-precision fine mask is very soft and extremely easily deformed To prevent the mask from deforming, in a design solution of the current conventional high-precision fine mask, a dummy (dummy) region usually needs to be set outside an effective evaporation region, and deformation of the high-precision fine mask caused by tension is reduced by using the dummy region. However, in the design solution of the current convention high-precision fine mask, an unetched entity portion exists between the effective region and the dummy region. Consequently, parameters of mechanical properties of the entire high-precision fine mask are different. Wrinkles are easily generated due to tension, generation of wrinkles causes color mixing of an evaporation product, and the color mixing seriously affects the yield rate of the AMOLED.

### BRIEF SUMMARY OF THE INVENTION

Based on, embodiments of this application, a mask is provided.

A mask is provided, including a dummy region and at least one effective evaporation region, where the dummy region is disposed on an outer side of the effective evaporation region;

the at least one effective evaporation region is provided with several first through holes; and

the dummy region is provided with several second through holes, the second through hole has a same shape as the first through hole, a dimension of the second through hole is equal to a dimension of the first through hole, and spacing between the second through hole is equal to spacing between the first through holes.

In one of the embodiments, each of the first through holes is arranged in a rectangular array, each of the second through holes is arranged in a rectangular array, row spacing between the second through holes is equal to row spacing between the first through holes, column spacing between the second through holes is equal to column spacing between the first through holes, and at least part of the second through holes are aligned with the first through holes.

In one of the embodiments, the row spacing and column spacing between the first through holes are equal.

In one of the embodiments, shape of the effective evaporation region is square.

In one of the embodiments, a shape of the effective evaporation region is round.

In one of the embodiments, a shape of the effective evaporation region is irregular.

In one of the embodiments, the second through holes pass through two opposite surfaces of the dummy region.

In one of the embodiments, the first through hole and the second through hole each have a round cross section, and a diameter of the first through hole is equal to a diameter of the second through hole.

In one of the embodiments, the first through hole and the second through hole each have a square cross section, and a width of the first through hole is equal to a width of the second through hole.

In one of the embodiments, the first through hole and the second through hole each have a polygonal cross section, and a width of the first through hole is equal to a width of the second through hole.

In one of the embodiments, each of the first through holes is arranged in a rectangular array, each of the second through holes is arranged in a rectangular array, row spacing between the second through holes is equal to row spacing between the first through holes, column spacing between the second through holes is equal to column spacing between the first through holes, and at least part of the second through holes are aligned with the first through holes; row spacing and column spacing between the first through holes are equal, a shape of the effective evaporation region is square, the second through holes pass through two opposite surfaces of the dummy region, the first through hole and the second through hole each have a round cross section, and a diameter of the first through hole is equal to a diameter of the second through hole.

For the mask, the second through holes are provided in the dummy region on the outer side of the effective evaporation region. The second through hole has the same shape, dimension, and spacing as the first through hole. Therefore, the dummy region has a same mechanical property as the effective evaporation region, and the dummy region has a same stress property as the effective evaporation region, so that it is not easy to produce wrinkles between the dummy region and the effective evaporation region, thereby effectively avoiding pixel color mixing, making an evaporation effect better, and improving a yield rate of a AMOLED.

Details of one or more embodiments of this application are provided in the following accompanying drawings and descriptions. Other features, objectives, and advantages of this application become apparent in the specification, the accompanying drawings, and the claims.

### BRIEF DESCRIPTION OF THE DRAWINGS

In order to more clearly describe the technical solutions of the embodiments of this application or in the prior art, the accompanying drawings required to describe the embodiments or the prior art are briefly described below. Apparently, the accompanying drawings described below are only some embodiments of this application. Those of ordinary skill in the art may further obtain accompanying drawings of other embodiments based on these accompanying drawings without inventive effort.

FIG. 1 is a schematic structural diagram of a mask according to an embodiment.

### DETAILED DESCRIPTION OF THE INVENTION

To facilitate understanding of this application, this application is more comprehensively described below with reference to the related accompanying drawings. Preferred embodiments of this application are provided in the accompanying drawings. However, this application can be implemented in many different forms, and is not limited to the embodiments described in this specification. In contrast, an objective of providing these embodiments is to provide a more thorough and comprehensive understanding of disclosed content of this application

It is to be noted that when one element is referred to as being “fixed” to other element, it may be directly on the other element or an intervening element may also be present. When one element is considered as being “connected” to the other element, it may be directly connected to the other element or an intervening element may be present simultaneously.

Unless otherwise defined all technical and scientific terms used in the specification are the same as meanings that are commonly understood by a person of ordinary skill in the art and that belong to this application. The terms used in the specification of this application are only for the purpose of describing specific embodiment, and are not intended to limit this application.

For example, a mask is provided, including a dummy region and at least one effective evaporation region. The dummy region is disposed on an outer side of the effective evaporation region. The at least one effective evaporation region is provided with several first through holes. The dummy region is provided with several second through holes, the second through hole has a same shape as the first through hole, a dimension of the second through hole is equal to a dimension of the first through hole, and spacing between the second through holes is equal to spacing between the first through holes.

In the foregoing embodiment, the second through holes are provided in the dummy region on the outer side of the effective evaporation region. The second through hole has the same shape, dimension, and spacing as the first through hole. Therefore, the dummy region has a same mechanical property as the effective evaporation region, and the dummy region has a same stress property as the effective evaporation region, so that it is not easy to produce wrinkles between the dummy region and the effective evaporation region, thereby effectively avoiding pixel color mixing, making an evaporation effect better, and improving a yield rate of a AMOLED.

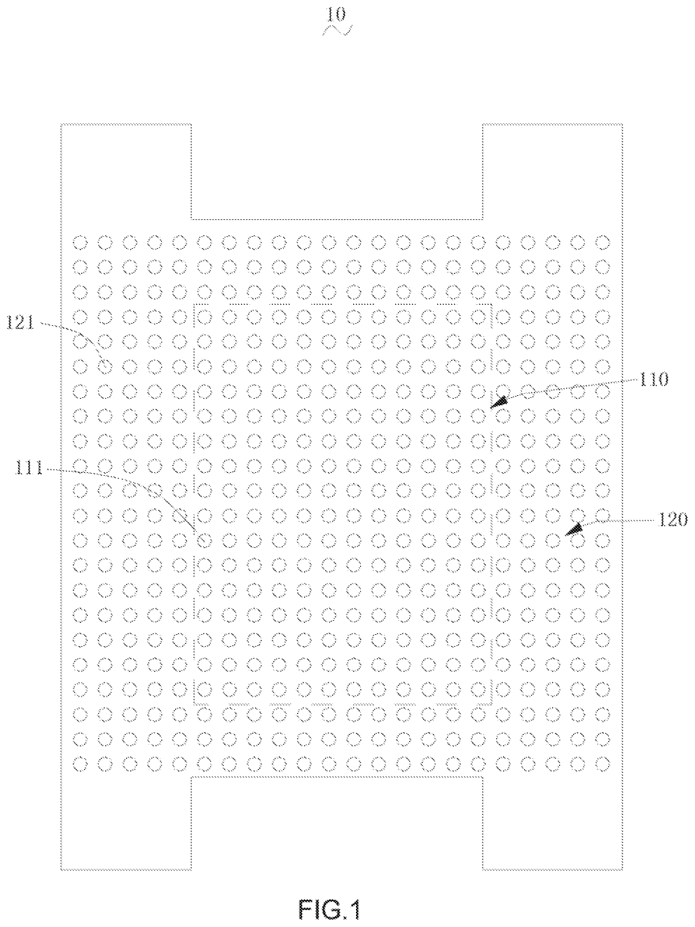

In an embodiment, as shown in FIG. 1, a mask 10 is provided, including a dummy region 120 and at least one effective evaporation region 110. The dummy region 120 is disposed on an outer side of the effective evaporation region 110. The at least one effective evaporation region 110 is provided with several first through holes 111. The dummy region 120 is provided with several second through holes 121, the second through hole 121 has a same shape as the first through hole 111, a dimension of the second through hole 121 is equal to a dimension of the first through hole 111, and spacing between the second through holes 121 is equal to spacing between the first through hole 111.

For example, a shape of a section of the second through hole 121 is the same as a shape of a section of the first through hole 111, and a shape of a cross section of the second through hole 121 is the same as a shape of a cross section of the first through hole 111. For example, a width of the second through hole 121 is equal to a width of the first through hole 111. For example, a width of the cross section of the second through hole 121 is equal to a width of the cross section of the first through hole 111. For example, spacing between two second through holes 121 is equal to spacing between two first through holes 111.

For example, the mask 10 is divided into the dummy region 120 and the effective evaporation region 110. Specifically, the effective evaporation region 110 is used to perform evaporation to form an effective pixel. For example, the effective evaporation region 110 is used to obtain a pixel pattern through evaporation, and an evaporated organic material is evaporated on a substrate through the first through holes 111 in the effective evaporation region 110. The first through holes 111 are pixel holes, so that the evaporated organic material passes through the first through holes 111 and is evaporated on the substrate.

The dummy region 120 is a non-evaporation region. The dummy region 120 may be considered as a region formed by the mask 10 extending on the outer side of the effective evaporation region 110, and the dummy region 120 is not used for evaporation.

It should be mentioned that the second through holes 121 are provided in the dummy region 120, but the second through holes 121 are not used for evaporation. In other words, no evaporated organic material passes through the second through holes 121. During use, a blocking film may be arranged in the dummy region 120, to block the second through holes 121 in the dummy region 120, thereby preventing the evaporated organic material from passing through the second through holes 121 in the dummy region 120. That is, for the mask 10 in this embodiment, in an evaporation process, evaporation for a pixel pattern is performed only in the effective evaporation region 110, and the dummy region 120 is not used for evaporation for the pixel pattern.

The second through holes 121 are provided in the dummy region 120, the second through hole 121 has the same shape as the first through hole 111, the dimension of the second through hole 121 is equal to the dimension of the first through holes 111, and the spacing between the second through holes 121 is equal to the spacing between the first through holes 111. Therefore, the dummy region 120 has a same structure as the effective evaporation region 110, the dummy region 120 has a same mechanical property as the effective evaporation region 110, and the dummy region 120 has a same stress property as the effective evaporation region 110, so that it is not easy to produce wrinkles between the dummy region 120 and the effective evaporation region 110 caused by tension, thereby effectively avoiding pixel color mixing, making an evaporation effect better, and improving a yield rate of a OLED

To prevent the evaporated organic material from passing through the second through holes 121 of the dummy region 120 to be deposited onto the substrate, for example, the mask 10 further includes a blocking film, the blocking film has a same shape as the dummy region 120, and the blocking film is aligned with the dummy region 120 and abuts against the dummy region 120. The blocking film is disposed in the second through holes 121 through blocking. In this way, during evaporation, the blocking film can isolate the organic material in the dummy region 120, thereby preventing the organic material from passing through the second through holes 121, and further making an evaporation effect better.

In an embodiment, each of the first through holes 111 is arranged in a rectangular array, each of the second through holes 121 is arranged in a rectangular array, row spacing between the second through holes 121 is equal to row spacing between the first through holes 111, column spacing between the second through holes 121 is equal to column spacing between the first through holes 111, and at least part of the second through holes 121 are aligned with the first through holes.

It should be understood that the shape of the dummy region 120 is different from a shape of the effective evaporation region 110. Therefore, not every row of second through holes 121 in the dummy region 120 is aligned with a row of first through holes 111 in the effective evaporation region 110, and not every column of second through holes 121 is aligned with a column of first through holes 111 in the effective evaporation region 110. Therefore, at least part of the second through holes 121 in the dummy region 120 are aligned with first through holes 111 in the effective evaporation region 110. For example, at least one row of the second through holes 121 is aligned with a row of the first through holes 111. For example, at least one column of the second through holes 121 is aligned with a column of the first through holes 111. In other words, in some second through holes 121 in the dummy region 120 that correspond to the first throng 11 holes 111, each row is aligned with a row of the first through holes 111, and each column is aligned with a column of the first through holes 111.

Specifically, in this embodiment, the first through holes 111 are arranged in several rows and several columns, row spacing between two adjacent rows of the first through holes 111 is equal, and column spacing between two adjacent columns of the first through holes 111 is equal. The second through holes 121 are arranged in several rows and several columns, row spacing between the second through holes 121 is equal to the row spacing between the first through holes 111, and column spacing between the second through holes 121 is equal to the column spacing between the first through holes 111. In addition, for some second through holes 121 aligned with the first through holes 111, each row of the second through holes 121 is aligned with a row of the first through holes 111, and each row of the second through holes 121 is aligned with a column of the first through holes 111. In this way, the second through holes 121 in the dummy region 120 have a same distribution structure as the first through holes 111 in the effective evaporation region 110, so that the dummy region 120 has a same structure as the effective evaporation region 110, the dummy region 120 has the same mechanical property as the effective evaporation region 110, and a better evaporation effect is made,

In an, embodiment, row spacing and column spacing between the first through holes 111 are equal, in other words, the row spacing between the first through holes 111 is equal to the column spacing between the first through holes 111. In this embodiment, the first through holes 111 in the effective evaporation region 110 are equally spaced in both a horizontal direction and a vertical direction. For example, row spacing and column spacing between the second through holes 121 are equal. For example, the row spacing between the second through holes 121 is equal to the column spacing between the second through holes 121. The second through holes 121 in the dummy region 120 are also equally spaced in both the horizontal direction and the vertical direction, so that a hole distance in the dummy region 120 is equal to a hole distance in the effective evaporation region 110, thereby helping avoid winkles generated on the mask 10 caused by tension, and further making an evaporation effect better.

It should be understood that, for a display region of a display screen corresponding to a pixel region formed through evaporation in the effective evaporation region 110, different display screens have different shapes. For example, a display screen of a mobile phone may be square or rectangular, a display screen on an electronic watch or a smart watch may be rectangular or round, and a display screen disposed on a display panel of a sensor such as a camera may be of an irregular shape. To meet different display screen requirements, in an embodiment, the shape of the effective evaporation region 110 is square. For example, the shape of the dummy region 120 is square, and the square dummy region 120 surrounds the square effective evaporation region 110. In this way, evaporation is performed in the effective evaporation region 110 to form a square pixel region on the substrate, and the display region of the corresponding display screen is square.

In an embodiment, the shape of the effective evaporation region 110 is round. For example, the dummy region 120 is of a ring shape, and the ring-shaped dummy region 120 surrounds the round effective evaporation region 110. In this way, evaporation is performed in the effective evaporation region 110 to form a round pixel region on the substrate, and the display region of the corresponding display screen is round.

In an embodiment, the shape of the effective evaporation region 110 is irregular. For example, the dummy region 120 is of a hollow irregular shape, and the shape of the dummy region 120 matches the shape of the effective evaporation region 110, and the dummy region 120 surrounds the effective evaporation region 110 of an irregular shape. In this way, evaporation is performed in the effective evaporation region 110 to form a pixel region of an irregular shape on the substrate, and the display region of the corresponding display screen is irregular.

In this way, based on the foregoing embodiments, manufacturing requirements of different display screens may be implemented.

To increase evaporation precision of the mask 10, for example, location precision of the first through hole 111 is less than 10 μm. For example, a width of the first through hole 111 is greater than or equal to 20 μm. For example, a width of the first through hole 111 is less than or equal to 30 μm. For example, location precision of the second through hole 121 is less than 10 μm. For example, a width of the second through hole 121 is greater than or equal to 20 μm. For example, a width of the second through hole 121 is less than or equal to 30 μm.

In an embodiment, the second through holes 121 pass through two opposite surfaces of the dummy region 120, in other words, the second through hole 121 is a penetrated hole, and two ends of the second through hole 121 are penetrated. In this way, the second through holes 121 have a same structure as the first through holes 111, and the dummy region 120 has a same mechanical property as the effective evaporation region 110, so that it is not easy to produce wrinkles between the dummy region 120 and the effective evaporation region 110, thereby effectively avoiding pixel color mixing, and making an evaporation effect better.

It should be understood that through holes on the mask 10 may be formed through etching. During evaporation, to prevent an organic material from penetrating through the second through holes 121 to the substrate, in an embodiment, the second through holes 121 are non-penetrated holes. For example, a blocking film is disposed in the second through hole 121. In this embodiment, two ends of the second through hole 121 are not penetrated. Specifically, when the mask 10 is being etched, semi-etching is performed on the dummy region 120 to form the second through holes 121, and full-etching is performed on the effective evaporation region 110 to form the first through holes 111. In other words, when the dummy region 120 is being etched, etching is performed in the second through hole 121 to form the blocking film, so that the two ends of the second through hole 121 are not penetrated. In this way, because the second through holes 121 having the same shape as the first through holes 111 in the effective evaporation region 110 are provided in the dummy region 120, the dummy region 120 has the same mechanical property as the effective evaporation region 110, thereby effectively avoiding generation of wrinkles. However, the second through holes 121 are not penetrated, so that the evaporated organic material can be effectively prevented from passing through. Therefore, the organic material can be prevented from being evaporated at a location of the dummy region 120 corresponding to the substrate, and a better evaporation effect is further made.

It should be understood that, to form different pixel patterns through evaporation, the first through hole 111 may be a round, square, or polygonal hole. In an embodiment, the first through hole 111 and the second through hole 121 each have a round cross section, and a diameter of the first through hole 111 is equal to a diameter of the second through hole 121 For example, a cross section of each of the first through hole 111 and the second through hole 121 is round. For example, the first through hole 111 and the second through hole 121 are separately round holes.

In an embodiment, the first through hole 111 and the second through hole 121 each have a square cross section, and a width of the first through hole 111 is equal to a width of the second through hole 121. In an embodiment, a cross section of each of the first through hole 111 and the second through hole 121 is square. For example, the first through hole 111 and the second through hole 121 are separately square holes.

In an embodiment, the first through hole 111 and the second through hole 121 each have a polygonal cross section, and a width of the first through hole 111 is equal to a width of the second through hole 121. In an embodiment, a cross section of each of the first through hole 111 and the second through hole 121 is polygonal. For example, the first through hole 111 and the second through hole 121 are separately polygonal holes.

In this way, the first through hole 111 is a round, square, or polygonal hole, or may be a through hole of an irregular shape n another embodiment. This is not described in detail in this embodiment. In this way, evaporation requirements of different pixel patterns can be met. In addition, because the second through holes 121 have the same shape as the first through holes 111, the dummy region 120 has a same stress property as the effective evaporation region 110 so that it is not easy to produce wrinkles between the dummy region 120 and the effective evaporation region 110 caused by tension, thereby effectively avoiding pixel color mixing, and making an evaporation effect better.

It should be mentioned that there may be a plurality of effective evaporation regions. For example, there are two effective evaporation regions, and the two effective evaporation regions are adjacently disposed. The dummy region is disposed on outer sides of the two effective evaporation regions and between the two effective evaporation regions. For another example, there are three effective evaporation regions. For another example, there are four effective evaporation regions. A manner of implementing the plurality of effective evaporation regions is not described in detail in this embodiment. A quantity of effective evaporation regions may be determined based on a display requirement of the display screen through etching on the mask. The second through hole having the same shape, dimension, and spacing with the first through hole in the effective evaporation region is disposed in the dummy region, so that the dummy region has a same stress property as the effective evaporation region.

In the foregoing embodiments, through holes are provided on the entire mask, unlike a traditional mask on which pixel holes are only disposed in an effective evaporation region. Pixels holes of the effective evaporation region of the entire mask have the same shape as pixel holes of an ineffective region (the dummy region), and the entire mask is fully covered with through holes, so that the through holes of the high-precision fine mask is relatively evenly distributed, the effective evaporation region and the dummy region of the entire mask have a same mechanical property, for example, the effective evaporation region and the dummy region have a same performance parameter in elasticity modulus and shear modulus, so that the high-precision fine mask is uniformly deformed under impact of tension, thereby avoiding generation of wrinkles on the high-precision fine mask, and reducing color mixing of light-emitting pixels of a product.

The technical features of the foregoing embodiments can be arbitrarily combined. In order to simplify the descriptions, all possible combinations of the technical features in the above embodiments have not been described. However, as long as there is no contradiction in the, combinations of these technical features, it should be considered as the scope described in this specification.

The foregoing embodiments only express several implementation manners of this application. Description of the foregoing embodiments is relatively specific and detailed, but cannot be understood as limiting the scope of the patent for the present invention. It should be noted that those of ordinary skill in the art may further make modifications and improvements without departing from the concept of this application, which all belong to the protection scope of this application. Therefore, the protection scope of the patent for this application shall be subject to the appended claims.

What is claimed is:

1. A mask, comprising a dummy region and at least one effective evaporation region, wherein the dummy region is disposed on an outer side of the effective evaporation region;
the at least one effective evaporation region is provided with several first through holes; and
the dummy region is provided with several second through holes, the second through hole has a same shape as the first through hole, a dimension of the second through hole is equal to a dimension of the first through hole, and spacing between the second through holes is equal to spacing between the first through holes.

2. The mask according to claim 1, wherein each of the first through holes is arranged in a rectangular array, each of the second through holes is arranged in a rectangular array, row spacing between the second through holes is equal to row spacing between the first through holes, column spacing between the second through holes is equal to column spacing between the first through holes, and at least part of the second through holes are aligned with the first through holes.

3. The mask according to claim 2, wherein the row spacing and the column spacing between the first through holes are equal.

4. The mask according to claim 1, wherein a shape of the effective evaporation region is square.

5. The mask according to claim 2, wherein a shape of the effective evaporation region is square.

6. The mask according to claim 3, wherein a shape of the effective evaporation region is square.

7. The mask according to claim 1, wherein a shape of the effective evaporation region is round.

8. The mask according to claim 2, wherein a shape of the effective evaporation region is round.

9. The mask according to claim 3, wherein a shape of the effective evaporation region is round.

10. The mask according to claim 1, wherein a shape of the effective evaporation region is irregular.

11. The mask according to claim 2, wherein shape of the effective evaporation region is irregular.

12. The mask according to claim 3, wherein a shape of the effective evaporation region is irregular.

13. The mask according to claim 1, wherein the second through holes pass through two opposite surfaces of the dummy region.

14. The mask according to claim 2, wherein the second through holes pass through two opposite surfaces of the dummy region.

15. The mask according to claim 3, wherein the second through holes pass through two opposite surfaces of the dummy region.

16. The mask according to claim 1, wherein the first through hole and the second through hole each have a round cross section, and a diameter of the first through hole is equal to a diameter of the second through hole.

17. The mask according to claim 2, wherein the first through hole and the second through hole each have a round cross section, and a diameter of the first through hole is equal to a diameter of the second through hole.

18. The mask according to claim 1, wherein the first through hole and the second through hole each have a square cross section, and a width of the first through hole is equal to a width of the second through hole.

19. The mask according to claim 1, wherein the first through hole and the second through hole each have a polygonal cross section, and a width of the first through hole is equal to a width of the second through hole.

20. The mask according to claim 1, wherein each of the first through holes is arranged in a rectangular array, each of the second through holes is arranged in a rectangular array, row spacing between the second through holes is equal to row spacing between the first through holes, column spacing between the second through holes is equal to column spacing between the first through holes, and at least part of the second through holes are aligned with the first through holes; the row spacing and the column spacing between the first through holes are equal, a shape of the effective evaporation region is square, the second through holes pass through two opposite surfaces of the dummy region, the first through hole and the second through hole each have a round cross section, and a diameter of the first through hole is equal to a diameter of the second through hole.
